(19) United States
(12) Patent Application Publication
(10) Pub. No.: US 2025/0266345 A1
(43) Pub. Date: Aug. 21, 2025

(54) METHODS AND APPARATUS TO REDUCE DISCOLORATION OF SOLDER RESISTS IN IMMERSION COOLING ENVIRONMENTS

(71) Applicant: Intel Corporation, Santa Clara, CA (US)

(72) Inventors: Shuren Qu, Gilbert, AZ (US); Bin Zou, Chandler, AZ (US); Md. Rezaul Hasan, Gilbert, AZ (US); Molla Shakirul Islam, Chandler, AZ (US); Sheng Li, Gilbert, AZ (US)

(73) Assignee: Intel Corporation, Santa Clara, CA (US)

(21) Appl. No.: 19/201,476

(22) Filed: May 7, 2025

(51) Int. Cl. H01L 23/498; H01L 21/02; H01L 21/48; H01L 23/00; H01L 23/44; H05K 1/02

(52) U.S. Cl. CPC H01L 23/49894; H01L 21/02118; H01L 21/481; H01L 23/44; H05K 1/0256; H01L 24/16; H01L 2224/16227; H01L 2224/16238; H05K 2201/0166

(57) ABSTRACT

Systems, apparatus, articles of manufacture, and methods to reduce discoloration of solder resists in immersion cooling environments are disclosed. An example apparatus includes a substrate. The example apparatus further includes a solder resist layer on an exterior surface of the substrate. The solder resist layer does not include a transition metal.

### BACKGROUND

An integrated circuit (IC) (e.g., semiconductor chip, semiconductor die, etc.) may be incorporated into an IC package by mounting the chip to an associated package substrate. The package substrate of an IC package enables electrical coupling of associated IC chip(s) to an external circuit board (e.g., a printed circuit board (PCB)). Package substrates of IC packages and PCBs often include layers of solder resist (e.g., solder masks) on their outer surfaces to provide electrical insulation over the underlying traces, contacts, and/or other metal features defining electrical interconnects and/or associated circuitry within the IC packages and PCBs.

### BRIEF DESCRIPTION OF THE DRAWINGS

FIG. 1 illustrates one or more example environments in which teachings of this disclosure may be implemented.

FIG. 2 illustrates an example electronic component constructed in accordance with teachings disclosed herein.

FIG. 3 illustrates the molecular structure of three types of metallic phthalocyanine pigments used in known solder resists.

FIG. 4 illustrates a known cooling environment at two different points in time while cooling an electronic component containing the known pigments shown in FIG. 3.

FIG. 5 represents the reaction between the pigment shown in FIG. 2 and the immersion cooling fluid shown in FIG. 4.

FIG. 6 shows the breakdown or degradation of the immersion cooling fluid shown in FIG. 4 based on the reaction with the pigment as detailed in FIG. 5.

FIG. 7 illustrates the molecular structure of a first example pigment that may be used in solder resist layers of the example electronic component of FIG. 2.

FIG. 8 illustrates the molecular structure of a second example pigment that may be used in solder resist layers of the example electronic component of FIG. 2.

FIG. 9 illustrates the molecular structure of a third example pigment that may be used in solder resist layers of the example electronic component of FIG. 2.

FIG. 10 illustrates an example cooling environment at two different points in time while cooling the example electronic component of FIG. 2.

FIG. 11 is a top view of a wafer including dies that may be included in an IC package constructed in accordance with teachings disclosed herein.

FIG. 12 is a cross-sectional side view of an IC device that may be included in an IC package constructed in accordance with teachings disclosed herein.

FIG. 13 is a cross-sectional side view of an IC device assembly that may include an IC package constructed in accordance with teachings disclosed herein.

FIG. 14 is a block diagram of an example electrical device that may include an IC package constructed in accordance with teachings disclosed herein.

FIG. 15 is a flowchart illustrating an example process for manufacturing either the circuit board or the package substrate of FIG. 2.

FIG. 16 is a flowchart illustrating an example process for assembling and/or operating the electronic component of FIG. 2 in the example immersion cooling environment of FIG. 10.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

The ever increasing demand for higher performance computing systems (e.g., central processing unit (CPU) servers and/or graphics processing unit (GPU) servers in data centers, accelerators, artificial intelligence (AI) computing, machine learning computing, cloud computing, edge computing, and the like) results in increased challenges associated with thermal management risks from ever increasing thermal design power (TDP) of high performance devices. With such high power consumption (which can be as high as or exceed 1000 W), current air cooling technologies for data centers are not sufficient to dissipate the heat generated by the high performance CPUs, GPUs, and/or AI chips. Furthermore, out of environmental protection considerations, many places have passed laws and/or regulations defining a target power usage effectiveness (PUE) for data centers. PUE targets specify that the power used to cool down a data center needs to be lower than a certain percentage (in some cases, <10%) of total energy consumption.

The use of liquids (e.g., immersion cooling) to cool electronic components has benefits over more traditional air cooling systems to meet demands of dissipating increasing amounts of heat (based on the increased power consumption (e.g., higher TDP) of electronic components) in a more energy efficient manner (based on the PUE targets). More particularly, relative to air, liquid has inherent advantages of higher specific heat (when no boiling is involved) and higher latent heat of vaporization (when boiling is involved). In other words, direct liquid cooling (e.g., immersion cooling) is much more efficient than air cooling, because liquids are significantly better at carrying away the heat. Furthermore, liquids allow for higher rack densities (e.g., up to and beyond 100 KW per rack). In air cooling systems for data centers, a majority of the costs are associated with heating, ventilation, and air conditioning (HVAC) systems, and fans on the servers. Immersion cooling systems on the other hand, typically have fewer moving parts, no refrigeration requirements, and/or fewer infrastructure requirements. In most cases, single-phase immersion cooling can reduce energy requirements of cooling systems by up to 90% with up to 50% reduction in overall data center energy usage compared to air cooling. This allows immersion-based data centers to meet many existing PUE targets.

A liquid cooling system can involve at least one of single-phase cooling or two-phase cooling. As used herein, single-phase cooling (e.g., single-phase immersion cooling) means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling (e.g., two-phase immersion cooling) means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, two-phase cooling liquids, or two-phase coolants. Notably, gases (e.g., air) can also be used to cool components and, therefore, may also be referred to as a cooling fluid and/or a coolant. However, as used herein, immersion cooling involves at least one cooling liquid (which may or may not change to the vapor phase when in use).

In direct immersion cooling, the liquid can be in direct contact with the electronic components to directly draw away heat from the electronic components. To enable the cooling fluid to be in direct contact with electronic components, the cooling fluid is electrically insulative (e.g., a dielectric liquid). Furthermore, to ensure all electronic components (e.g., CPUs, GPUs, AI chips, etc.) perform reliably, it is important that the materials used in such components are chemically compatible with the cooling fluid. Not only is this important to the reliable operation of the electronic components immersed in the cooling fluid, chemically compatible materials are also important to the ability of the cooling fluid to perform its function of drawing away heat from the electronic components. Example systems, apparatus, and associated methods disclosed herein improve immersion cooling systems and/or associated cooling processes.

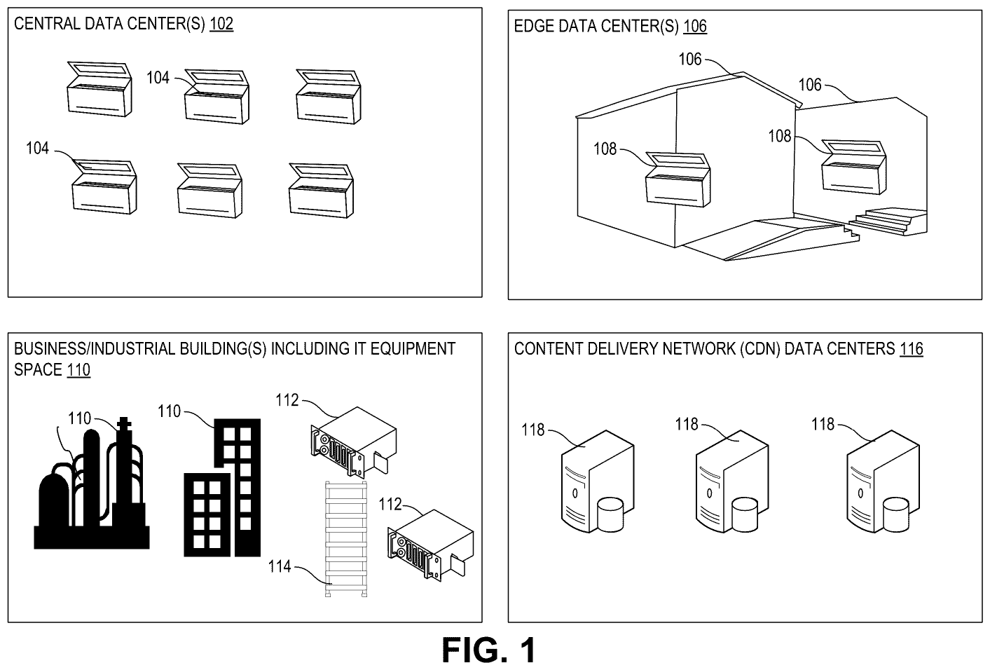

FIG. 1 illustrates one or more example environments (e.g., liquid cooling environments) in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., electromagnetic interference (EMI), vibration, extreme temperatures), and/or enable submergibility. Example housings may include power circuitry to provide power for stationary and/or portable implementations, such as alternating current (AC) power inputs, direct current (DC) power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted.

Although a certain number of cooling tank(s) and other component(s) are shown in the example environments of FIG. 1, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein can be sized such that only a tool can reach into the enclosure because the structure may be supported by, for a utility pole or radio tower, or a larger structure.

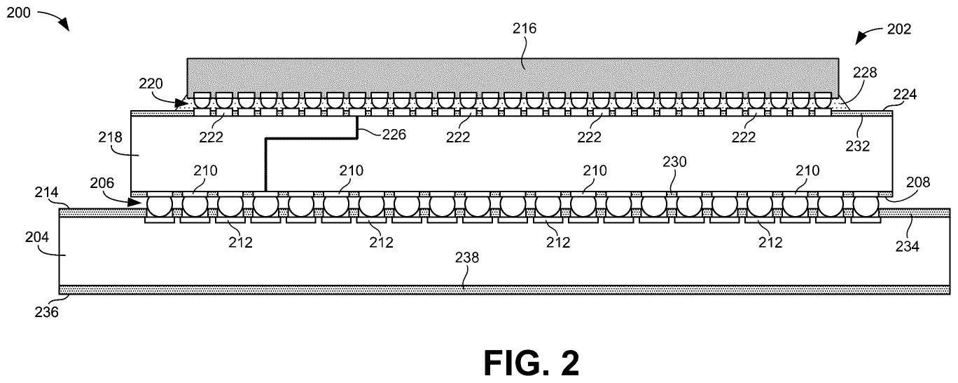

FIG. 2 illustrates an example electronic component 200 (e.g., electronic device) constructed in accordance with teachings disclosed herein. The example electronic component 200 can be immersed in a liquid coolant within any one of the immersion tanks 104, 108 discussed above in connection with FIG. 1. In the illustrated example, the electronic component 200 includes an example IC package 202 that is electrically and mechanically coupled to an underlying circuit board 204 (e.g., a server board, a motherboard, a printed circuit board (PCB), a substrate, etc.) via an array of first interconnects 206 on a package mounting surface 208 (e.g., a first surface, a bottom surface) of the IC package 202. In FIG. 2, the first interconnects 206 are shown as balls protruding from corresponding contact pads 210. However, in some examples, the IC package 202 may include pads, lands, pins, and/or any other type(s) of interconnects, in addition to or instead of the balls shown, to enable the electrical coupling of the IC package 202 to the circuit board 204.

As shown in the illustrated example, the first interconnects 206 are directly coupled to corresponding contact pads 212 distributed along a first surface 214 (e.g., top surface, front surface) of the circuit board 204. In the illustrated example, the contact pads 212 are represented as pads or lands. However, in other examples, the contact pads 212 can be any other suitable shape to receive and/or electrically couple with the first interconnects 206 on the bottom surface 208 of the IC package 202. In some examples, the connections between the first interconnects 206 and the contact pads 212 can include solder joints, micro bumps, combinations of metallic (e.g., copper) pillars and solder, etc. In some examples, the interconnects 206 are indirectly connected to the circuit board 204 by way of a socket positioned between the IC package 202 and the circuit board 204.

In this example, the IC package 202 includes a semiconductor die 216 (e.g., silicon die), sometimes also referred to as a chip or chiplet, that is mounted to a package substrate 218. The die 216 can provide any suitable type of functionality (e.g., data processing, memory storage, etc.). While the example IC package 202 of FIG. 2 includes only one die 216, in other examples, the IC package 202 may have more than one die. In some such examples, the one or more dies can be positioned side-by-side. Additionally or alternatively, in some examples, one or more dies may be stacked on top of one another. That is, in some examples, the die 216 is implemented by a die package including multiple dies arranged in a stacked formation. For example, the die 216 can include a stack of Dynamic Random Access Memory (DRAM) dies arranged on top of a memory controller die to form a memory die stack. In some examples, the IC package 202 includes one or more dies embedded within the package substrate 218. In some examples, the semiconductor die 216 is enclosed by a package lid (e.g., a mold compound, an integrated heat spreader (IHS)). However, in this example, the package lid is omitted, thereby leaving the semiconductor die 216 exposed or bare.

As shown in the illustrated example, the die 216 is electrically and mechanically coupled to the package substrate 218 via an array of second interconnects 220. In FIG. 2, the interconnects 220 are shown as bumps. In some examples, the interconnects 220 can include solder joints, micro bumps, combinations of metallic (e.g., copper) pillars and solder, etc. In other examples, the interconnects 220 may include directly bonded or “hybrid bonded” metallic interconnects. In other examples, the interconnects 220 may be any other type of electrical connection in addition to or instead of the bumps shown (e.g., balls, pins, pads, pillars, wire bonding, etc.).

As shown in FIG. 2, when the die 216 is mounted to the package substrate 218, the second interconnects 220 are physically connected and electrically coupled to contact pads 222 on a die mounting surface 224 (e.g., a second surface, an upper surface, a top surface, etc.) of the package substrate 218. The contact pads 222 on the die mounting surface 224 of the package substrate 218 are electrically coupled to the interconnects 206 on the package mounting surface 208 (e.g., the bottom, external surface) of the package substrate 218 (e.g., a surface opposite the die mounting surface 224) via internal interconnects 226 within the package substrate 218. As a result, there is a continuous electrical path between the second interconnects 220 of the die 216 and the first interconnects 206 electrically coupled to the circuit board 204 that pass through the internal interconnects 226 and both contact pads 210, 222 at either end of the internal interconnects 226.

In some examples, an underfill material 228 is disposed between the die 216 and the package substrate 218 around and/or between individual ones of the second interconnects 220. In other examples, the underfill material 228 is omitted. In some examples, a mold compound used for a package lid (omitted in the illustrated example) is used as an underfill material that surrounds the second interconnects 220. In some examples, the IC package 202 includes additional passive components, such as surface-mount resistors, capacitors, and/or inductors disposed on the package mounting surface 208 of the package substrate 218 and/or the die mounting surface 224 of the package substrate 218.

In the illustrated example of FIG. 2, the outer surfaces of both the package substrate 218 and the circuit board 204 are defined by respective layers of solder resist (e.g., solder resist material, solder masks). That is, the first (bottom) surface 208 of the package substrate 218 is defined by a first solder resist 230 and the second (upper) surface 224 of the package substrate 218 is defined by a second solder resist 232. Similarly, the first (top) surface 214 of the package substrate 218 is defined by a third solder resist 234 and a second surface 236 (e.g., a bottom surface, back surface) of the circuit board 204 is defined by a fourth solder resist 238.

In the illustrated example, the first solder resist 230 has a thickness corresponding to the thickness of the contact pads 210 distributed along the corresponding bottom surface 208 of the package substrate 218. However, in other examples, the thickness of the first solder resist 230 can be less than the thickness of the corresponding contact pads 210 (as in the case of the second solder resist 232 relative to the corresponding contact pads 222 shown in FIG. 2) or more than the thickness of the corresponding contact pads 210 (as in the case of the third solder resist 234 relative to the corresponding contact pads 212 shown in FIG. 2). Likewise, the thickness of the second and third solder resists 232, 234 can be less than, equal to, or greater than the thickness of the corresponding contacts pads 212, 222.

In the illustrated example, an outer surface of the first solder resist 232 (e.g., the bottom surface 208) is flush with outer surfaces of the corresponding contact pads 210. However, in other examples, outer surfaces of the contact pads 210 can protrude from (e.g., extend beyond) the outer surface of the first solder resist 232 (as in the case of the contact pads 222 relative to the corresponding second solder resist 232 shown in FIG. 2) or be recessed relative to the outer surface of the first solder resist 232 (as in the case of the contact pads 212 relative to the corresponding third solder resist 232 shown in FIG. 2). Likewise, outer surfaces of the contact pads 212, 222 can be recessed relative to, flush with, or protrude from (e.g., extend beyond) the outer surface of the corresponding second and third solder resists 232, 234.

In some examples, any of the solder resists 230, 232, 234, 238 can be in the same plane as the corresponding contact pads 210, 212, 222 (as in the case of the first and second solder resists 230, 232 shown in the illustrated example) or in a different plane (e.g., over top of) the corresponding contact pads 210, 212, 222 (as in the case of the third solder resist 234 shown in the illustrated example). In some examples, one or more of the solder resists 230, 232, 234, 238 are omitted.

In some examples, the solder resists 230, 232, 234, 238 include a pigment that provides the solder resists with a color (e.g., green) that results in a relatively strong contrast with fiducial markers or other features on the underlying substrates (e.g., the package substrate 218 for the first and second resists 230, 230 and the circuit board 204 for the third and fourth solder resists 234, 238). The strong contrast made possible by the pigment is important to enable optical analysis of an underlying substrate (e.g., for defect detection, for alignment of components, etc.). Unlike known solder resists, the pigment used to color the solder resists 230, 232, 234, 238 of the illustrated example is different from phthalocyanine with a metal center (also referred to herein as metallic phthalocyanine). That is, the example solder resists 230, 232, 234, 238 do not include a phthalocyanine chemical structure with a metal center.

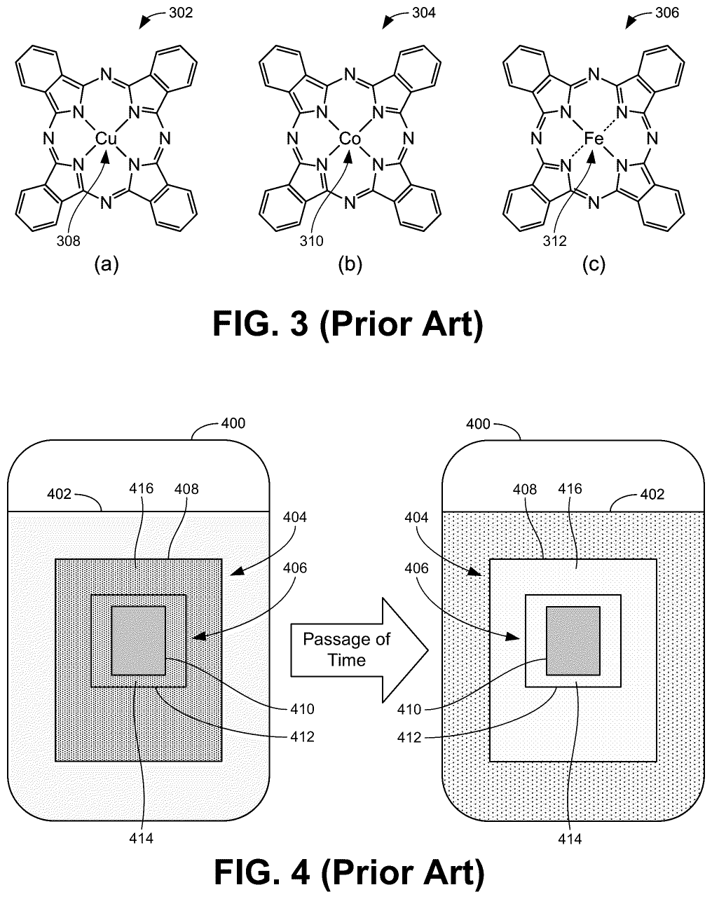

FIG. 3 illustrates the molecular structure of three types of metallic phthalocyanine pigments used in known solder resists including copper phthalocyanine (CuPc) 302, cobalt phthalocyanine (CoPc) 304, and iron phthalocyanine (FePc) 306. All three types of phthalocyanine shown in FIG. 3 include a metal (e.g., a transition metal) at the center of the molecular structure. Specifically, as shown in FIG. 3, the molecular structure of CuPc 302 includes carbon, hydrogen, and nitrogen with a copper atom 308 at the center of the structure. The molecular structure of CoPc 304 is similar except that the center of the structure includes a cobalt atom 310. The molecular structure of FePc 306 has a similar molecular structure except that the center of the structure includes an iron atom 312.

While the metallic phthalocyanine pigments 302, 304, 306 shown in FIG. 3 serve an important purpose (e.g., provide strong contrast between the solder resist and other features on an associated substrate for purposes of image analysis), such pigments present problems when used in conjunction with immersion cooling systems. As discussed above, many immersion cooling systems involve the complete or partial submersion of electronic components (e.g., servers, circuit boards with IC packages attached thereto, etc.) in an immersion coolant (e.g., a hydrocarbon cooling fluid). Solder resists that use known pigments (e.g., phthalocyanine with a metal center) are not compatible with such cooling fluids. Rather, such cooling fluids are reactive with the known solder resist pigments and cause the metallic elements (e.g., the copper atom 308, the cobalt atom 310, or the iron atom 312) within the pigment to leach out of the center of the phthalocyanine structure and into the cooling fluid.

The separation of the metallic element from the rest of the phthalocyanine chemical structure is problematic for at least two reasons. First, the loss of the metal center of the pigment into the cooling fluid results in the discoloration of the solder resist. That is, solder resist on an IC package substrate and/or a PCB will lose its color overtime when immersed in many known hydrocarbon cooling fluids. This is problematic because the loss of coloration of the solder resist undermines the ability to reliably perform image analysis of the associated substrate. The second problem that arises from the leaching out of the metallic elements of known pigments into cooling fluids is the contamination of the cooling fluids with such elements. More particularly, in some instances, the metallic elements that leach out of the center of pigments with a phthalocyanine molecular structure serve as a catalyst that accelerates degradation and/or aging of the fluid. Such increases in the rate at which cooling fluid degrades lead to increases in downtime to purge a cooling tank of old cooling fluid and replace it with new fluid. Furthermore, byproducts of the degradation, such as peroxides and organic acids, can increase in the cooling fluid. Such byproducts can end up depositing on contact pads, terminals, and/or exposed circuitry of submerged electronic components, thereby disrupting the proper functioning of the circuitry components. Further still, degradation byproducts in the cooling fluid can also cause damage to other assembly materials (e.g., sealants, die side component encapsulants, thermal interface materials, etc.).

The foregoing problems are graphically represented in FIG. 4, which represents an immersion cooling tank 400 filled with a cooling fluid 402 (e.g., coolant) in which a known electronic component 404 that includes solder resist layers containing phthalocyanine pigment with a metal center. Specifically, FIG. 4 represents conditions both before (lefthand side) and after (righthand side) the metal center of the pigment has leached out into the cooling fluid 402. More particularly, the known electronic component 404 includes an IC package 406 mounted to a circuit board 408 (e.g., a PCB). As shown in FIG. 4, the IC package 406 includes a semiconductor die 410 mounted on a package substrate 412. In FIG. 4, the package substrate 412 includes a first layer of solder resist 414 and the circuit board 408 includes a second layer of solder resist 416. Both layers of solder resist 414, 416 are represented with the same shading to indicate they both have the same color based on the same pigment. As noted above, the lefthand side of FIG. 4 represents the environment before any leaching out of the metallic elements from the pigment (e.g., when the electronic component 404 is initially immersed in the cooling fluid 402). Thus, as shown, the layers of solder resist 414, 416 are relatively dark (e.g., they still have their intended color) and the cooling fluid 402 is relatively light with few, if any, impurities. By contrast, the righthand side of FIG. 4 represents the environment after some period of time during which the metal center of the metallic phthalocyanine pigment has leached out into the cooling fluid 402. At this point, both layers of solder resist 414, 416 have become lighter and discolored while the cooling fluid 402 has become contaminated.

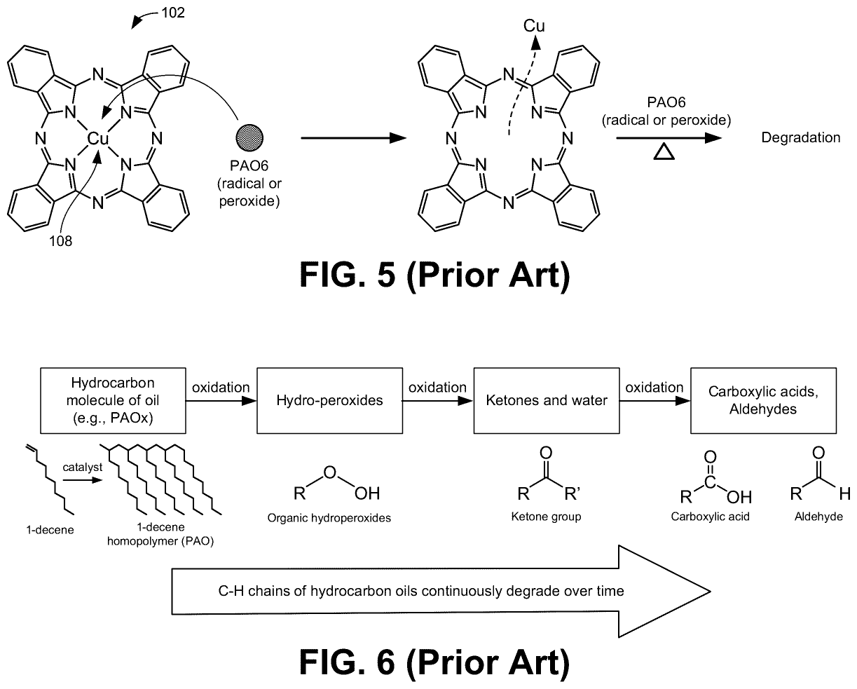

FIGS. 5 and 6 provide further detail explaining the process of discoloration of a solder resist colored with CuPc 302 and the resulting degradation of a cooling fluid (e.g., the cooling fluid 402). Specifically, FIG. 5 represents the reaction between the CuPc 302 and a hydrocarbon cooling fluid. In this instance, the cooling fluid is polyalphaolefin 6 (PAO6). A free radical and/or peroxide generated from PAO6 thermal degradation interacts with the copper atom 308 at the center of the CuPc 302 causing the copper atom 308 to break free from the phthalocyanine structure and cause degradation to the cooling fluid. More particularly, the free radicals or peroxides generated from PAO6 degradation attack the Cu—N coordination bonds of the CuPc 302, thereby causing the copper atom 308 to leave the phthalocyanine conjugation structure.

FIG. 6 shows the breakdown or degradation of PAO6 as a result of the free copper atoms 308 leaching into the cooling fluid. The copper atoms 308 serves as a catalyst for oxidation that produces hydro-peroxides. Further oxidation can give rise to ketones, which can lead to carboxylic acids and/or aldehydes. As noted above, such byproducts can end up depositing on exposed circuitry features of electronic components (e.g., the electronic component 404 in FIG. 4) to disrupt the function of such circuitry and/or otherwise damage materials (e.g., sealants, die side component encapsulants, thermal interface materials, etc.) on the electronic components.

Significantly, as noted in FIG. 6, the degradation of hydrocarbons degrades overtime and there is no viable recovery mechanism. However, the discoloration of the layers of solder resist 414, 416 due to the metal elements of the phthalocyanine pigment leaching into the cooling fluid, as shown in FIG. 4, can significantly accelerate this degradation. Indeed, experimental testing of a hydrocarbon immersion fluid (e.g., PAO6) was found to fail the first 1000-hour readout during a reliability stress test as a result of discoloration of solder resist materials included in electronic components immersed in the cooling fluid. Failure within this timeframe of a stress test indicates less than 2 years of normal operation life. Raman spectroscopy analysis confirms that the cause of the discoloration and the associated accelerated degradation of the cooling fluid can be attributed to the breakdown of the molecular structure of the pigment used in the solder resists. Specifically, the output of a Raman analysis of a non-discolored circuit board shows several characteristic peaks indicative of the pigment with the metal center. However, these characteristic peaks do not appear in the output of a Raman analysis of a circuit board that has become discolored after submersion in an immersion cooling fluid for a prolonged period at an elevated temperature.

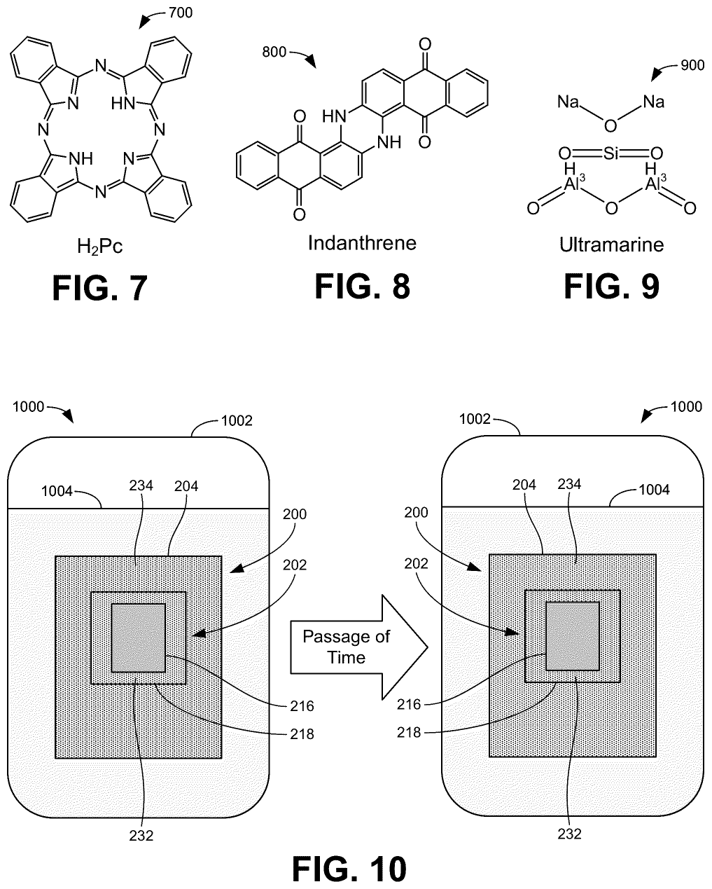

The problems of discoloration of solder resist and the associated acceleration of degradation of cooling fluid as detailed in connection with FIGS. 4-6 based on the solder resist including a pigment having one of the molecular structures shown in FIG. 3 are avoided with the electronic component 200 of FIG. 2 because a different pigment is used in the solder resists 230, 232, 234, 238. Specifically, the different pigment used in the solder resists 230, 232, 234, 238 of electronic component 200 of FIG. 2 is chemically compatible (e.g., non-reactive) with hydrocarbon cooling fluids. Some examples of such pigments are shown in FIGS. 7-9. Specifically, FIG. 7 illustrates the molecular structure of a first example pigment 700 corresponding to non-metallic phthalocyanine (H2Pc), FIG. 8 illustrates the molecular structure of a second example pigment 800 corresponding to indanthrene, and FIG. 9 illustrates the molecular structure of a third example pigment 900 corresponding to ultramarine.

As shown in FIG. 7, the first pigment 700 includes nearly the same molecular structure as the different types of metallic phthalocyanine shown in FIG. 3. However, unlike the molecular structures shown in FIG. 3, the molecular structure of the first pigment 700 does not include a metal (e.g., a transition metal) at the center. Indeed, the first pigment does not include a metal at all (which is why it is referred to herein as a non-metallic phthalocyanine). More particularly, non-metallic phthalocyanine (e.g., the first pigment 700) includes carbon, nitrogen, and hydrogen. Inasmuch as the first pigment 700 does not include a metal at a center of its molecular structure, there is no metal to react with and leach into a cooling fluid used to cool an associated electronic component including a solder resist (e.g., the solder resists 230, 232, 234, 238 of FIG. 2) containing the first pigment 700. As a result, solder resists colored using the first pigment 700 as disclosed herein significantly reduce (e.g., prevent) degradation of cooling fluid into which a substrate containing the solder resist is submerged.

Furthermore, experimental testing confirms that solder resists that include the first pigment 700 retain their color for much longer than solder resists colored with known pigments (e.g., metallic phthalocyanine). Specifically, a stress test was performed on different substrates covered in solder resist containing different pigments by submerging the substrates in a hydrocarbon cooling fluid for 200 hours at an elevated temperature of 125 degrees Celsius. Following this stress test, the substrates covered with a solder resist containing the (known) metallic phthalocyanine pigment were completely discolored whereas the substrates covered with solder resist containing the example first pigment 700 retained all or nearly all (at least 90% or higher (e.g., at least 95%, at least 98%, at least 99%)) of the pigment color. That is, the discoloration of the solder resist containing the first pigment 700 resulting from the stress test is less than 10% or less (e.g., less than 5%, less than 2%, less than 1%, etc.).

Similar to FIG. 7, the example second pigment 800 shown in FIG. 8 (e.g., indanthrene) also includes a molecular structure devoid of metal. Rather, as shown in the illustrated example, the second pigment 800 includes carbon, hydrogen, nitrogen, and oxygen. Experimental testing has confirmed that the second pigment 800 does not react with or leach into hydrocarbon cooling fluids and retains at least 90% or more (e.g., at least 95%, at least 98%, at least 99%) coloration following a stress test of submersion in a cooling fluid for 200 hours at 125 degrees Celsius.

The example third pigment 900 shown in FIG. 8 (e.g., ultramarine) has a molecular structure containing metals including sodium and aluminum (along with oxygen, silicon, and hydrogen). However, the third pigment 900 does not include any transition metals. Moreover, the molecular structure of the third pigment 900 is significantly different than the molecular structure of metallic phthalocyanine (shown in FIG. 3). As a result, the same challenges do not arise. That is, the third pigment 900 does not react with or leach into hydrocarbon cooling fluids and is able to retain coloration for extended periods of time much longer than metallic phthalocyanine pigments. More particularly, as with the first and second example pigments 700, 800 noted above, the third example pigment 900 retains at least 90% or more (e.g., at least 95%, at least 98%, at least 99%) coloration following a stress test of submersion in a cooling fluid for 200 hours at 125 degrees Celsius.

While three example pigments 700, 800, 900 are shown and described, other organic or inorganic pigments that do not have a metallic phthalocyanine molecular structure (e.g., phthalocyanine with a metal center) can also be used as a pigment for solder resist materials without accelerating the degradation of cooling fluids and/or becoming discolored following exposure to (e.g., immersion in) such cooling fluids.

FIG. 10 illustrates an example cooling environment 1000 in which teachings disclosed herein may be implemented at two different points in time. As shown in the illustrated example, the cooling environment 1000 includes an immersion cooling tank 1002 filled with a cooling fluid 1004 (e.g., coolant) in which the example electronic component 200 of FIG. 2 is submerged to be cooled. In some examples, the cooling tank 1002 corresponds to one of the immersion tanks 104, 108 discussed above in connection with FIG. 1. The example cooling fluid 1004 is any suitable hydrocarbon immersion cooling fluid such as polyalphaolefin (PAO) based fluids, mineral oil based fluids, synthetic oils, transformer oils, engine oils, etc.

In this example, the electronic component 200 is oriented vertically within the tank 1002 in a position with a top of the IC package 202 facing out of the page. Thus, in the illustrated example, the semiconductor die 216 is in front of the package substrate 218, which is in front of the underlying circuit board 204. As such, in this orientation, the third solder resist 234 on the circuit board 204 is visible (whereas the fourth solder resist 238 is not because it is on the side of the circuit board facing into page of FIG. 10). Likewise, the second solder resist 234 on the package substrate 218 of the IC package 202 is visible (whereas the first solder resist 230 is not because it is on the side of the package substrate 218 facing into page of FIG. 10).

In this example, the second and third solder resists 232, 234 shown (as well as the first and fourth solder resists 230, 238 that are not shown) are colored with a pigment other than metallic phthalocyanine. In some examples, the pigment included in the solder resists 230, 232, 234, 238 includes a phthalocyanine structure without a metal center (e.g., the pigment is a non-metallic phthalocyanine pigment such as the first pigment 700 of FIG. 7). Stated differently, in some examples, the solder resists 230, 232, 234, 238 (and/or, more particularly, the pigments of the solder resists) do not include a transition metal (e.g., iron, cobalt, or copper). In some examples, the pigment in the solder resists 230, 232, 234, 238 includes a molecular structure different from the phthalocyanine structure. That is, in some examples, the pigment is a non-phthalocyanine pigment (e.g., the pigment is not a phthalocyanine compound). For instance, in some examples, the pigment in the solder resists 230, 232, 234, 238 corresponds to the second pigment 800 of FIG. 8. In some examples, the pigment in the solder resists 230, 232, 234, 238 corresponds to the third pigment 900 of FIG. 9. In some examples, different ones of the solder resists 230, 232, 234, 238 include a different pigment. For instance, in some examples, the first and second solder resists 230, 232 on the package substrate 218 include one pigment while the third and fourth solder resists 234, 238 on the circuit board 204 include a different pigment. In some examples, one or more of the solder resists 230, 232, 234, 238 include more than one type of pigment.

As noted above, FIG. 10 illustrates the example cooling environment 1000 at two different points in time. Specifically, the left side of FIG. 10 represents conditions when the example electronic component 200 of FIG. 2 is initially placed within the immersion cooling fluid 1004 inside the immersion cooling tank 1002. By contrast, the right side of FIG. 10 represents the environment after an extended period of time (e.g., one or more years or more and upwards of 5 years or more). As shown in the illustrated example, the solder resists 232, 234 retain their color over time (as represented by the consistent shading on both sides of FIG. 10). That is, the solder resists 232, 234 do not undergo any significant discoloration unlike what is shown in FIG. 4 based on the solder resists 414, 416 being colored with metallic phthalocyanine. As a result of the solder resists 232, 234 retaining their color, the cooling fluid 1004 remains substantially the same over time (as represented by the consistent shading on both sides of FIG. 10). That is, degradation of the cooling fluid 1004 is reduced (e.g., prevented) because there are no materials from the solder resists 230, 232, 234, 238 leaching into the cooling fluid 1004 unlike what is shown in FIG. 4.

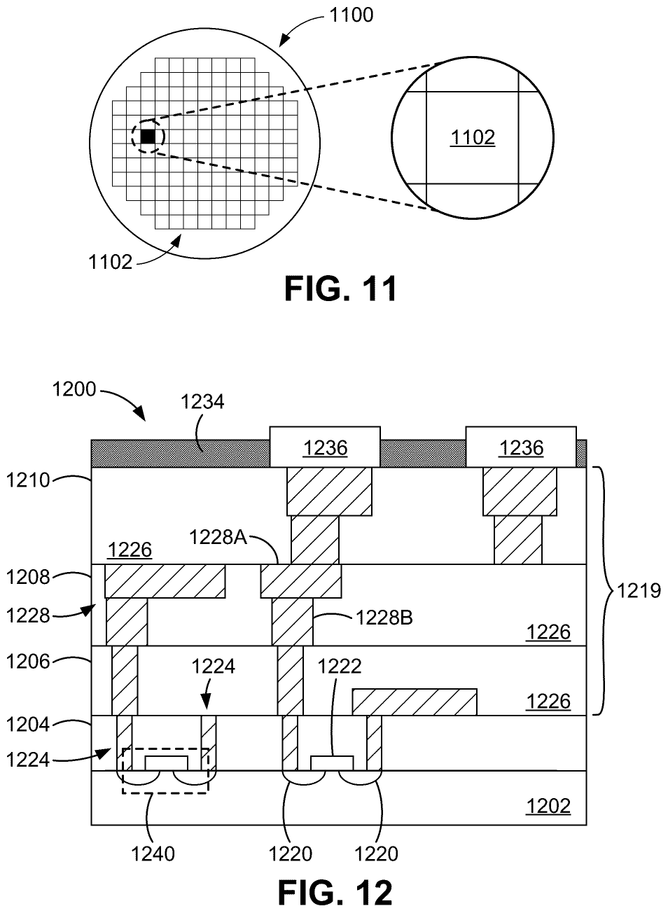

The example electronic component 200 disclosed herein may be included in any suitable electronic component. FIGS. 11-14 illustrate various examples of apparatus that may include or be included in the electronic component 200 disclosed herein.

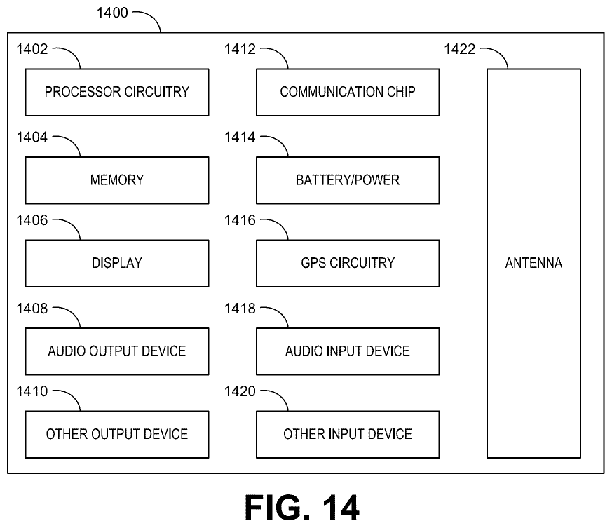

FIG. 11 is a top view of a wafer 1100 and dies 1102 that may be included in the electronic component 200 of FIG. 2 and/or FIG. 10 (e.g., as the die 216). The wafer 1100 includes semiconductor material and one or more dies 1102 having circuitry. Each of the dies 1102 may be a repeating unit of a semiconductor product. After the fabrication of the semiconductor product is complete, the wafer 1100 may undergo a singulation process in which the dies 1102 are separated from one another to provide discrete “chips.” The die 1102 includes one or more transistors (e.g., some of the transistors 1240 of FIG. 12, discussed below), supporting circuitry to route electrical signals to the transistors, passive components (e.g., traces, resistors, capacitors, inductors, and/or other circuitry), and/or any other components. In some examples, the die 1102 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1102. For example, a memory array of multiple memory circuits may be formed on a same die 1102 as programmable circuitry (e.g., the processor circuitry 1402 of FIG. 14) and/or other logic circuitry. Such memory may store information for use by the programmable circuitry. The example electronic component 200 disclosed herein may be manufactured using a die-to-wafer assembly technique in which some dies are attached to a wafer 1100 that includes others of the dies, and the wafer 1100 is subsequently singulated.

FIG. 12 is a cross-sectional side view of an IC device 1200 that may be included in the example electronic component 200 (e.g., in the die 216). One or more of the IC devices 1200 may be included in one or more dies 1102 (FIG. 11). The IC device 1200 may be formed on a die substrate 1202 (e.g., the wafer 1100 of FIG. 11) and may be included in a die (e.g., the die 1102 of FIG. 11). The die substrate 1202 may be a semiconductor substrate including semiconductor materials including, for example, n-type or p-type materials systems (or a combination of both). The die substrate 1202 may include, for example, a crystalline substrate formed using a bulk silicon or a silicon-on-insulator (SOI) substructure. In some examples, the die substrate 1202 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an IC device 1200 may be used. The die substrate 1202 may be part of a singulated die (e.g., the dies 1102 of FIG. 11) or a wafer (e.g., the wafer 1100 of FIG. 11).

The IC device 1200 may include one or more device layers 1204 disposed on and/or above the die substrate 1202. The device layer 1204 may include features of one or more transistors 1240 (e.g., metal oxide semiconductor field-effect transistors (MOSFETs)) formed on the die substrate 1202. The device layer 1204 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1240 may include a gate 1222 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1240 along the source-channel-drain direction, the gate electrode may include a U-shaped structure that includes a bottom portion substantially parallel to the surface of the die substrate 1202 and two sidewall portions that are substantially perpendicular to the top surface of the die substrate 1202. In other examples, at least one of the metal layers that form the gate electrode may be a planar layer that is substantially parallel to the top surface of the die substrate 1202 and does not include sidewall portions substantially perpendicular to the top surface of the die substrate 1202. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of corresponding transistor(s) 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1220 may be formed using one or more alternate semiconductor materials such as germanium or a group III-V material or alloy. In further examples, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the IC device 1200.

The interconnect structures 1228 may be arranged within the interconnect layers 1206-1210 to route electrical signals according to a wide variety of designs (in particular, the arrangement is not limited to the particular configuration of interconnect structures 1228 depicted in FIG. 12). Although a particular number of interconnect layers 1206-1210 is depicted in FIG. 12, examples of the present disclosure include IC devices having more or fewer interconnect layers than depicted.

In some examples, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and/or out of the page from the perspective of FIG. 12. The vias 1228b may be arranged to route electrical signals in a direction of a plane that is substantially perpendicular to the surface of the die substrate 1202 upon which the device layer 1204 is formed. In some examples, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some examples, the dielectric material 1226 disposed between the interconnect structures 1228 in different ones of the interconnect layers 1206-1210 may have different compositions; in other examples, the composition of the dielectric material 1226 between different interconnect layers 1206-1210 may be the same.

A first interconnect layer 1206 (referred to as Metal 1 or “M1”) may be formed directly on the device layer 1204. In some examples, the first interconnect layer 1206 may include lines 1228a and/or vias 1228b, as shown. The lines 1228a of the first interconnect layer 1206 may be coupled with contacts (e.g., the S/D contacts 1224) of the device layer 1204.

A second interconnect layer 1208 (referred to as Metal 2 or “M2”) may be formed directly on the first interconnect layer 1206. In some examples, the second interconnect layer 1208 may include vias 1228b to couple the lines 1228a of the second interconnect layer 1208 with the lines 1228a of the first interconnect layer 1206. Although the lines 1228a and the vias 1228b are structurally delineated with a line within each interconnect layer (e.g., within the second interconnect layer 1208) for the sake of clarity, the lines 1228a and the vias 1228b may be structurally and/or materially contiguous (e.g., simultaneously filled during a dual-damascene process) in some examples.

A third interconnect layer 1210 (referred to as Metal 3 or “M3”) (and additional interconnect layers, as desired) may be formed in succession on the second interconnect layer 1208 according to similar techniques and/or configurations described in connection with the second interconnect layer 1208 or the first interconnect layer 1206. In some examples, the interconnect layers that are “higher up” in the metallization stack 1219 in the IC device 1200 (i.e., further away from the device layer 1204) may be thicker.

The IC device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to other external devices. For example, solder bonds may be formed on the one or more conductive contacts 1236 to mechanically and/or electrically couple a chip including the IC device 1200 with another component (e.g., a circuit board). The IC device 1200 may include additional or alternate structures to route the electrical signals from the interconnect layers 1206-1210; for example, the conductive contacts 1236 may include other analogous features (e.g., posts) that route the electrical signals to external components.

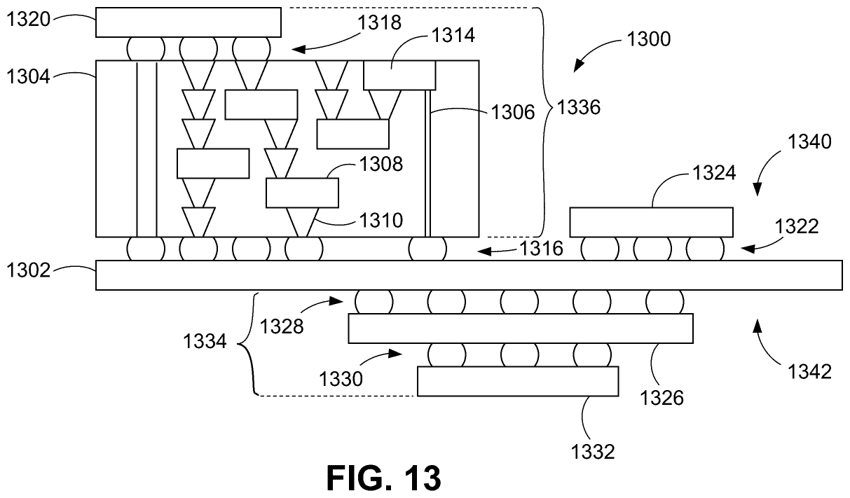

FIG. 13 is a cross-sectional side view of an IC device assembly 1300 that may include the electronic component 200 and/or the example IC package 202 disclosed herein. In some examples, the IC device assembly corresponds to the electronic component 200. The IC device assembly 1300 includes a number of components disposed on a circuit board 1302 (which may be, for example, a motherboard). The IC device assembly 1300 includes components disposed on a first face 1340 of the circuit board 1302 and an opposing second face 1342 of the circuit board 1302; generally, components may be disposed on one or both faces 1340 and 1342. Any of the IC devices discussed below with reference to the IC device assembly 1300 may take the form of the example electronic component 200 and/or the example IC package 202 of FIG. 2 and/or FIG. 10.

In some examples, the circuit board 1302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1302. In other examples, the circuit board 1302 may be a non-PCB substrate.

The IC device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), male and female portions of a socket, an adhesive, an underfill material, and/or any other suitable electrical and/or mechanical coupling structure.

The package-on-interposer structure 1336 may include an IC package 1320 coupled to an interposer 1304 by coupling components 1318. The coupling components 1318 may take any suitable form for the application, such as the forms discussed above with reference to the coupling components 1316. Although a single IC package 1320 is shown in FIG. 13, multiple IC packages may be coupled to the interposer 1304; indeed, additional interposers may be coupled to the interposer 1304. The interposer 1304 may provide an intervening substrate used to bridge the circuit board 1302 and the IC package 1320. The IC package 1320 may be or include, for example, a die (the die 1102 of FIG. 11), an IC device (e.g., the IC device 1200 of FIG. 12), or any other suitable component. Generally, the interposer 1304 may spread a connection to a wider pitch or reroute a connection to a different connection. For example, the interposer 1304 may couple the IC package 1320 (e.g., a die) to a set of BGA conductive contacts of the coupling components 1316 for coupling to the circuit board 1302. In the example illustrated in FIG. 13, the IC package 1320 and the circuit board 1302 are attached to opposing sides of the interposer 1304; in other examples, the IC package 1320 and the circuit board 1302 may be attached to a same side of the interposer 1304. In some examples, three or more components may be interconnected by way of the interposer 1304.

In some examples, the interposer 1304 may be formed as a PCB, including multiple metal layers separated from one another by layers of dielectric material and interconnected by electrically conductive vias. In some examples, the interposer 1304 may be formed of an epoxy resin, a fiberglass-reinforced epoxy resin, an epoxy resin with inorganic fillers, a ceramic material, or a polymer material such as polyimide. In some examples, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through-silicon vias (TSVs) 1306. The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The IC device assembly 1300 may include an IC package 1324 coupled to the first face 1340 of the circuit board 1302 by coupling components 1322. The coupling components 1322 may take the form of any of the examples discussed above with reference to the coupling components 1316, and the IC package 1324 may take the form of any of the examples discussed above with reference to the IC package 1320.

The IC device assembly 1300 illustrated in FIG. 13 includes a package-on-package structure 1334 coupled to the second face 1342 of the circuit board 1302 by coupling components 1328. The package-on-package structure 1334 may include a first IC package 1326 and a second IC package 1332 coupled together by coupling components 1330 such that the first IC package 1326 is disposed between the circuit board 1302 and the second IC package 1332. The coupling components 1328, 1330 may take the form of any of the examples of the coupling components 1316 discussed above, and the IC packages 1326, 1332 may take the form of any of the examples of the IC package 1320 discussed above. The package-on-package structure 1334 may be configured in accordance with any of the package-on-package structures known in the art.

FIG. 14 is a block diagram of an example electrical device 1400 that may include one or more of the example electronic component 200 and/or the example IC package 202 of FIG. 2 and/or FIG. 10. For example, any suitable ones of the components of the electrical device 1400 may include one or more of the device assemblies 1300, IC devices 1200, or dies 1102 disclosed herein, and may be arranged in the example electronic component 200 and/or the example IC package 202. A number of components are illustrated in FIG. 14 as included in the electrical device 1400, but any one or more of these components may be omitted or duplicated, as suitable for the application. In some examples, some or all of the components included in the electrical device 1400 may be attached to one or more motherboards. In some examples, some or all of these components are fabricated onto a single system-on-a-chip (SoC) die.

Additionally, in various examples, the electrical device 1400 may not include one or more of the components illustrated in FIG. 14, but the electrical device 1400 may include interface circuitry for coupling to the one or more components. For example, the electrical device 1400 may not include a display 1406, but may include display interface circuitry (e.g., a connector and driver circuitry) to which a display 1406 may be coupled. In another set of examples, the electrical device 1400 may not include an audio input device 1418 (e.g., microphone) or an audio output device 1408 (e.g., a speaker, a headset, earbuds, etc.), but may include audio input or output device interface circuitry (e.g., connectors and supporting circuitry) to which an audio input device 1418 or audio output device 1408 may be coupled.

The electrical device 1400 may include programmable circuitry 1402 (e.g., one or more processing devices). The programmable circuitry 1402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1400 may include a memory 1404, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1404 may include memory that shares a die with the programmable circuitry 1402. This memory may be used as cache memory and may include embedded dynamic random access memory (eDRAM) or spin transfer torque magnetic random access memory (STT-MRAM).

In some examples, the electrical device 1400 may include a communication chip 1412 (e.g., one or more communication chips). For example, the communication chip 1412 may be configured for managing wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1412 may operate in accordance with Code Division Multiple Access (CDMA), Time Division Multiple Access

(TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other examples. The electrical device 1400 may include an antenna 1422 to facilitate wireless communications and/or to receive other wireless communications (such as AM or FM radio transmissions).

In some examples, the communication chip 1412 may manage wired communications, such as electrical, optical, or any other suitable communication protocols (e.g., the Ethernet). As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as global positioning system (GPS), EDGE, GPRS, CDMA, WiMAX, LTE, EV-DO, or others. In some examples, a first communication chip 1412 may be dedicated to wireless communications, and a second communication chip 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display 1406 (or corresponding interface circuitry, as discussed above). The display 1406 may include any visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any device that generates an audible indicator, such as speakers, headsets, or earbuds.

The electrical device 1400 may include an audio input device 1418 (or corresponding interface circuitry, as discussed above). The audio input device 1418 may include any device that generates a signal representative of a sound, such as microphones, microphone arrays, or digital instruments (e.g., instruments having a musical instrument digital interface (MIDI) output).

The electrical device 1400 may include GPS circuitry 1416. The GPS circuitry 1416 may be in communication with a satellite-based system and may receive a location of the electrical device 1400, as known in the art.

The electrical device 1400 may include any other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include any other input device 1420 (or corresponding interface circuitry, as discussed above). Examples of the other input device 1420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1400 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

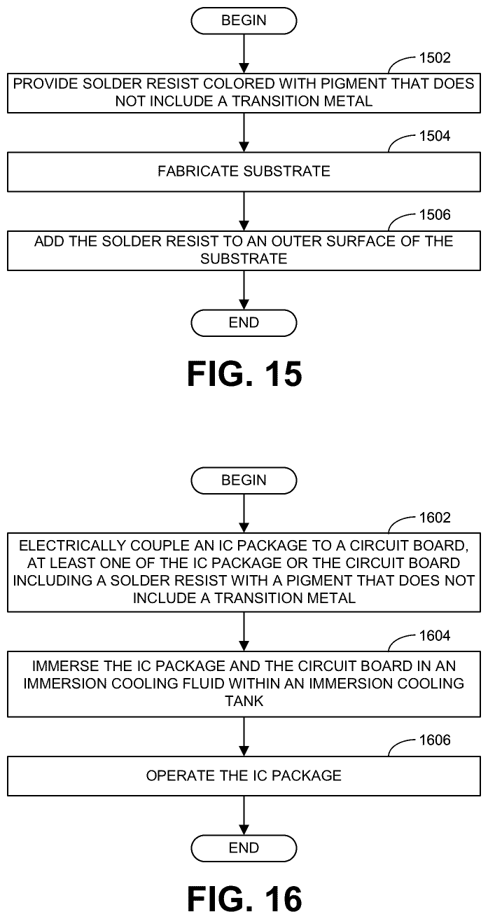

FIG. 15 is a flowchart illustrating an example method of manufacturing either the circuit board 204 or the package substrate 218 of FIG. 2. In some examples, some or all of the operations outlined in the example method of FIG. 15 are performed automatically by fabrication equipment that is programmed to perform the operations. Although the example method of manufacture is described with reference to the flowchart illustrated in FIG. 15, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example

The example method of FIG. 15 begins at block 1502 by providing a solder resist (e.g., any of the solder resists 230, 232, 234, 238) with a pigment (e.g., any of the pigments 700, 800, 900) that does not include a transition metal. At block 1504, the example method includes fabricating a substrate. In some examples, the substrate fabricated at block 1504 corresponds to the circuit board 204 of FIG. 1. In such examples, any suitable fabrication processes for circuit boards may be employed. In other examples, the substrate fabricated at block 1504 corresponds to the example package substrate 218. In such examples, any suitable fabrication processes for package substrate may be employed. At block 1506, the example method includes adding the solder resist to an outer surface of the substrate. Thereafter, the example method of FIG. 15 ends.

FIG. 16 is a flowchart illustrating an example process for assembling and/or operating the electronic component 200 of FIG. 2 in the example immersion cooling environment 1000 of FIG. 10. In some examples, some or all of the operations outlined in the example method of FIG. 16 are performed automatically by fabrication equipment that is programmed to perform the operations. Although the example method of manufacture is described with reference to the flowchart illustrated in FIG. 16, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 16 begins at block 1602 by electrically coupling an IC package (e.g., the IC package 202) to a circuit board (e.g., the circuit board 204) where at least one of the IC package or the circuit board includes a solder (e.g., any of the solder resists 230, 232, 234, 238) with a pigment (e.g., any of the pigments 700, 800, 900) that does not include a transition metal. At block 1604, the example method includes immersing the IC package and the circuit board in an immersion cooling fluid (e.g., the cooling fluid 1004) within an immersion cooling tank (e.g., the tank 1002). At block 1606, the example method includes operating the IC package. Thereafter, the example method of FIG. 16 ends.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that reduce discoloration of solder resists when submerged in immersion cooling fluids. In some examples, the solder resist is colored with one or more pigments compatible with the cooling fluids. Some such example pigments include non-metallic phthalocyanine (e.g., phthalocyanine pigments that do not have a metal center). Other example pigments used in example solder resists disclosed herein are pigments that do not include a phthalocyanine chemical structure. The chemical compatibility of the example solder resists disclosed herein reduce (e.g., prevent) degradation of the cooling fluids into which an electronic component containing the solder resists is submerged. As a result, the useful life of such cooling fluids can be significantly extended, thereby improving the efficiency and reliability of liquid cooling systems.

Further examples and combinations thereof include the following:

Example 1 includes an apparatus comprising a substrate, and a solder resist layer on an exterior surface of the substrate, the solder resist layer does not include a transition metal.

Example 2 includes any preceding clause(s) of example 1, wherein the substrate is a package substrate of an integrated circuit package.

Example 3 includes any preceding clause(s) of any one or more of examples 1-2, wherein the solder resist layer does not include a metallic phthalocyanine pigment having a metal center.

Example 4 includes any preceding clause(s) of any one or more of examples 1-3, wherein the solder resist layer includes a pigment including an organic material.

Example 5 includes any preceding clause(s) of any one or more of examples 1-4, wherein the solder resist layer includes a pigment including an inorganic material.

Example 6 includes any preceding clause(s) of any one or more of examples 1-5, wherein the solder resist layer includes a pigment including non-metallic phthalocyanine.

Example 7 includes any preceding clause(s) of any one or more of examples 1-6, wherein the solder resist layer includes a pigment including ultramarine.

Example 8 includes any preceding clause(s) of any one or more of examples 1-7, wherein the solder resist layer includes a pigment including indanthrene.

Example 9 includes an apparatus comprising a semiconductor die, a substrate, and a solder mask on the substrate, the solder mask colored by a pigment that does not include a transition metal.

Example 10 includes any preceding clause(s) of example 9, wherein the substrate is a package substrate of an integrated circuit package, the integrated circuit package including the semiconductor die.

Example 11 includes any preceding clause(s) of any one or more of examples 9-10, wherein the substrate is a printed circuit board.

Example 12 includes any preceding clause(s) of any one or more of examples 9-11, wherein the pigment includes phthalocyanine without a metal center.

Example 13 includes any preceding clause(s) of any one or more of examples 9-12, wherein the pigment is a non-phthalocyanine pigment.

Example 14 includes any preceding clause(s) of any one or more of examples 9-13, wherein the pigment includes carbon, oxygen, and hydrogen but does not include copper, does not include cobalt, and does not include iron.

Example 15 includes any preceding clause(s) of any one or more of examples 9-14, wherein the pigment includes nitrogen.

Example 16 includes any preceding clause(s) of any one or more of examples 9-15, wherein the pigment includes silicon, aluminum, and sodium.

Example 17 includes a method comprising fabricating a substrate, and adding a solder resist to an exterior surface of the substrate, the solder resist layer does not include a metallic phthalocyanine pigment having a metal center.

Example 18 includes any preceding clause(s) of example 17, wherein the solder resist includes a pigment that provides a color to the solder resist, the solder resist to retain the color after at least 200 hours of immersion in an immersion cooling fluid.

Example 19 includes any preceding clause(s) of any one or more of examples 17-18, wherein the solder resist is to retain the color after the at least 200 hours of immersion in the immersion cooling fluid at a temperature of at least 125 degrees Celsius.

Example 20 includes any preceding clause(s) of any one or more of examples 17-19, wherein the immersion cooling fluid is a hydrocarbon cooling fluid.

Example 21 includes a system comprising an immersion cooling fluid, a tank to hold the immersion cooling fluid, and an electronic device to be immersed in the immersion cooling fluid, the immersion cooling fluid to draw heat away from the electronic device, the electronic device including a substrate having a solder resist, the solder resist including a pigment that provides a color to the solder resist, the solder resist to retain the color after at least 200 hours of immersion in the immersion cooling fluid.

Example 22 includes any preceding clause(s) of example 21, wherein the pigment includes a molecular structure devoid of metal.

Example 23 includes any preceding clause(s) of any one or more of examples 21-22, wherein the solder resist is to retain the color after the at least 200 hours of immersion in the immersion cooling fluid at a temperature of at least 125 degrees Celsius.

Example 24 includes any preceding clause(s) of any one or more of examples 21-23, wherein the immersion cooling fluid is a hydrocarbon cooling fluid.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a substrate; and
a solder resist layer on an exterior surface of the substrate, the solder resist layer does not include a transition metal.

2. The apparatus of claim 1, wherein the substrate is a package substrate of an integrated circuit package.

3. The apparatus of claim 1, wherein the solder resist layer does not include a metallic phthalocyanine pigment having a metal center.

4. The apparatus of claim 1, wherein the solder resist layer includes a pigment including an organic material.

5. The apparatus of claim 1, wherein the solder resist layer includes a pigment including an inorganic material.

6. The apparatus of claim 1, wherein the solder resist layer includes a pigment including non-metallic phthalocyanine.

7. The apparatus of claim 1, wherein the solder resist layer includes a pigment including ultramarine.

8. The apparatus of claim 1, wherein the solder resist layer includes a pigment including indanthrene.

9. An apparatus comprising:
a semiconductor die;
a substrate; and
a solder mask on the substrate, the solder mask colored by a pigment that does not include a transition metal.

10. The apparatus of claim 9, wherein the substrate is a package substrate of an integrated circuit package, the integrated circuit package including the semiconductor die.

11. The apparatus of claim 9, wherein the substrate is a printed circuit board.

12. The apparatus of claim 9, wherein the pigment includes phthalocyanine without a metal center.

13. The apparatus of claim 9, wherein the pigment is a non-phthalocyanine pigment.

14. The apparatus of claim 9, wherein the pigment includes carbon, oxygen, and hydrogen but does not include copper, does not include cobalt, and does not include iron.

15. The apparatus of claim 14, wherein the pigment includes nitrogen.

16. The apparatus of claim 14, wherein the pigment includes silicon, aluminum, and sodium.

17. A method comprising:
fabricating a substrate; and
adding a solder resist to an exterior surface of the substrate, the solder resist layer does not include a metallic phthalocyanine pigment having a metal center.

18. The method of claim 17, wherein the solder resist includes a pigment that provides a color to the solder resist, the solder resist to retain the color after at least 200 hours of immersion in an immersion cooling fluid.

19. The method of claim 18, wherein the solder resist is to retain the color after the at least 200 hours of immersion in the immersion cooling fluid at a temperature of at least 125 degrees Celsius.

20. The method of claim 18, wherein the immersion cooling fluid is a hydrocarbon cooling fluid.
